(19) United States
(12) Patent Application Publication
(10) Pub. No.: US 2021/0088591 A1
(43) Pub. Date: Mar. 25, 2021

(54) METHOD AND SYSTEM FOR BATTERY-MANAGEMENT IN DEVICES

(71) Applicant: Samsung Electronics Co., Ltd., Suwon-si (KR)

(72) Inventors: Arunava NAHA, Bangalore (IN); Achyutha Krishna KONETI, Bangalore (IN); Piyush TAGADE, Bangalore (IN); Ashish KHANDELWAL, Bangalore (IN); Seongho HAN, Suwon-si (KR); Krishnan S. HARIHARAN, Bangalore (IN)

(21) Appl. No.: 17/025,973

(22) Filed: Sep. 18, 2020

(30) Foreign Application Priority Data
Sep. 19, 2019 (IN) 201941037887
Aug. 20, 2020 (IN) 201941037887

(51) Int. Cl. G01R 31/367; H02J 7/00; G01R 31/392; G01R 31/3842; H01M 10/48; H01M 10/42

(52) U.S. Cl. CPC G01R 31/367; H02J 7/005; G01R 31/392; H01M 2010/4271; H01M 10/48; H01M 10/425; G01R 31/3842

(57) ABSTRACT

The present subject refers to a method for battery fault diagnosis and prevention of hazardous conditions. The method comprises determining a plurality of parameters defined as one or more of current, voltage, or state of charge during operation of a battery-powered device. Further, one or more likelihood ratios related to malfunctioning of the battery are evaluated based on determined parameters. At least one of: a current battery-state or a type of current battery state are determined based on the one or more likelihood ratios as evaluated.

### CROSS-REFERENCE TO RELATED APPLICATIONS

This application is based on and claims priority under 35 U.S.C. § 119 to Indian Provisional Patent Application No. 201941037887 filed on Sep. 19, 2019 and Indian Non-Provisional Patent Application No. 201941037887 filed on Aug. 20, 2020 in the Indian Patent Office, the disclosures of which are herein incorporated by reference in their entirety.

### BACKGROUND

### 1. Field

The present subject matter relates to battery state monitoring and in particular relates to smart mechanism for fault diagnosis.

### 2. Description of Related Art

With the advent of technologies, devices and systems are becoming more power hungry, and require high energy density battery. In addition, the smart devices leave minimum room to accommodate the batteries. Importantly, appropriate safety measures need to be taken so that hazardless device operation can be achieved. However, any rechargeable battery may become faulty due to various reasons such as over-discharging, over charging, internal short circuit, mechanical abuse, etc. The faults of such kinds may cause battery swelling, puncture of battery casing, release of hazardous gas and chemicals, thermal runaway, etc. which are all potential threats to the human safety and can also impact the brand equity. Hence, any faults in the battery should be detected at the earliest and preventive action should be taken as per the type and severity of the fault. Estimation of the severity level of the fault incurred during operation is also important to prevent any further damage.

A rechargeable-battery may become faulty due to manufacturing defects or non-standard usages of the device. For example, a non-standard charging adapter may cause over-charging fault in the battery, mechanical damage of the battery may cause serious physical damage to the battery electrodes and separators. Such faulty batteries may swell, release harmful chemicals and gas, heat up and undergo thermal runway. The rechargeable battery fault detection and isolation should be quick.

After detection of fault, some measure is undertaken to prevent any hazardous incident that may be caused by the faulty battery. Under practical usages, the charging and discharging of the batteries are mostly partial. There can be no resting period for few charge-discharge cycles for some application such as the smart phone's batteries. Under such scenarios, most of the battery fault detection algorithms will fail or provide erroneous results. Today rechargeable batteries are getting used from small internet of things (IoT) based devices to large systems such as EVs and Aircrafts. They have different on-board computation capabilities.

There lies at-least a need to evolve a low-computational complexity battery-fault detection systems. More specifically, the fault detection method should not wait for multiple charge-discharge cycles of battery data to decide the battery condition.

There lies at-least a need to evolve battery-fault detection systems which can be used uniformly from small devices to large systems.

### SUMMARY

This summary is provided to introduce a selection of concepts, in a simplified format, that are further described in the detailed description of this disclosure. This summary is not intended to identify key or essential inventive concepts of this disclosure, nor is this summary intended to determine the scope of this disclosure.

The present subject refers to a method for battery fault diagnosis and prevention of hazardous conditions. The method comprises determining a plurality of parameters defined as one or more of current, voltage and state of charge during operation of a battery-powered device. Further, one or more likelihood ratios related to malfunctioning of the battery are evaluated based on determined-parameters. At least one of: a current battery-state and a type of current battery state are determined based on the one or more likelihood ratios as evaluated.

In other embodiment, the present subject matter refers a method for fault diagnosis in a battery. The method comprises monitoring one or more of charging and discharging related parameters of one or more batteries for a pre-defined time duration. A log of the monitored-parameters associated with healthy and faulty states of the batteries is created. One or more of charging and discharging parameters of the at-least one battery under observation are determined. The determined parameters of the battery under-observation are mapped mapping to correlate with the parameters within created log. Accordingly, a faulty or healthy-state of the battery under observation is diagnosed.

The present subject matter at-least applies data-driven techniques to the recorded battery current, voltage and SOC data from the BMS to detect different types of battery-faults. The proposed solution also determines the severity of the problem and takes preventive actions depending on the type of the fault and its severity to prevent any hazardous incident and helps ensure user safety. Two different data driven techniques can be applied to solve the fault diagnosis problem. One of them is ML based method and another one is pure statistical likelihood ratio based method. Both the techniques can also be applied together to get more robust fault estimation. The proposed method can detect faults in almost real-time (<1 min), which gives enough lead-time to prevent any subsequent hazardous incidents.

This present subject matter is capable of detecting at least the following faults, i.e. over discharging fault, over charging fault, internal short circuit fault, mechanical abuse fault. In other words, the present subject matter detects the faulty battery, identifies the type of fault and then takes actions to prevent any hazardous incident depending upon the type of fault and fault severity. The proposed method detects faults using partial discharge data, which is an essential requirement for online battery fault detection algorithm because charging-discharging is mostly partial under practical usage.

The solution rendered by the present subject matter may be integrated in the existing BMS of smart phones, EVs and other equipment with no additional hardware. The proposed method may be implement with battery current, voltage and SOC measurements, which are already being measured in any standard BMS. Low computational complexity of the underlying logic makes it suitable to implement in small and low power devices such as personal digital assistances (PDA), IoT based devices, etc. to large systems such as electric vehicles (EV) and Aircrafts.

To further clarify advantages and features of the present disclosure, a more particular description will be rendered by reference to specific embodiments thereof, which is illustrated in the appended drawings. It is appreciated that these drawings depict certain embodiments of this disclosure and are therefore not to be considered limiting of its scope. The disclosure will be described and explained with additional specificity and detail with the accompanying drawings.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates method steps, according to an embodiment of the present subject matter;

FIGS. 2a and 2b illustrate method steps, in accordance with an embodiment of the present subject matter;

FIG. 3 illustrates a system, in accordance with an embodiment of the present subject matter;

FIG. 4 illustrates an example control flow; in accordance with an embodiment of the present subject matter;

FIG. 5 illustrates an example control flow, in accordance with an embodiment of the present subject matter;

FIG. 6 illustrates an example control flow, in reference to an embodiment of the present subject matter;

FIGS. 7a-7c illustrate example control flows, in reference to an embodiment of the present subject matter;

FIG. 8 illustrates an experiment test case, in reference to an embodiment of the present subject matter;

FIG. 9 illustrates an experiment test case, in reference to an embodiment of the present subject matter;

FIG. 10 illustrates an experiment test case, in reference to an embodiment of the present subject matter; and

FIG. 11 illustrates an example implementation of method steps of FIG. 1 and FIG. 2, in accordance with an embodiment of the present subject matter,

Further, skilled artisans will appreciate that elements in the drawings are illustrated for simplicity and may not have been necessarily been drawn to scale. For example, the flow charts illustrate the method in terms of the most prominent steps involved to help to improve understanding of aspects of the present disclosure. Furthermore, in terms of the construction of the device, one or more components of the device may have been represented in the drawings by conventional symbols, and the drawings may show specific details that are pertinent to understanding the embodiments of the present disclosure so as not to obscure the drawings with details that will be readily apparent to those of ordinary skill in the art having benefit of the description herein.

### DETAILED DESCRIPTION

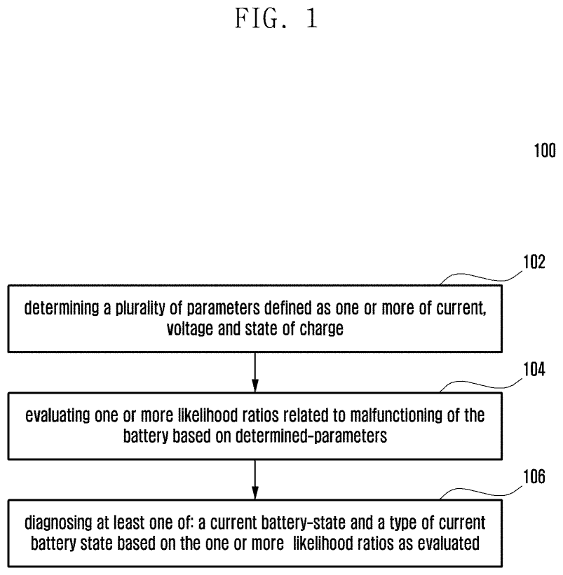

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

For the purpose of promoting an understanding of the principles of this disclosure, reference will now be made to the example embodiments illustrated in the drawings and specific language will be used to describe the same. It will nevertheless be understood that no limitation of the scope of this disclosure is thereby intended, such alterations and further modifications in the illustrated system, and such further applications of the principles of this disclosure as illustrated therein being contemplated as would normally occur to one skilled in the art to which this disclosure relates.

It will be understood by those skilled in the art that the foregoing general description and the following detailed description are explanatory of this disclosure and are not intended to be restrictive thereof.

Reference throughout this specification to “an aspect”, “another aspect” or similar language means that a particular feature, structure, or characteristic described in connection with the embodiment is included in at least one embodiment of the present disclosure. Thus, appearances of the phrase “in an embodiment”, “in another embodiment” and similar language throughout this specification may, but do not necessarily, all refer to the same embodiment.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components.

Unless otherwise defined, all technical and scientific terms used herein have the same meaning as commonly understood by one of ordinary skilled in the art to which this disclosure belongs. The system, methods, and examples provided herein are illustrative only and not intended to be limiting.

As illustrated in the example of in FIG. 1, the present subject matter refers to a method 100 for battery fault diagnosis and prevention of hazardous conditions. The method comprises determining (step 102) a plurality of parameters defined as one or more of current, voltage and state of charge during operation of a battery-powered device. Such determining of parameters during the operation of the device corresponds to a determination performed during charging and discharging of the battery associated with the battery powered device. The plurality of parameters are determined based on operation of a plurality of battery management systems (BMS) configured to track the operation of the battery with the device.

Further, the method comprises evaluating (step 104) one or more likelihood ratios related to malfunctioning of the battery based on determined-parameters. The likelihood ratios (LR) are evaluated based on estimation of probability density functions (PDFs) which are in-turn based on a historical monitoring of the current, voltage and state of charge. In other embodiment, the LRs are obtained based on a real-time monitoring of current, voltage and state of charge of the battery based on a database of the stored PDFs.

In another implementation, the likelihood of battery-failure is computed at least based on a training-phase comprising training a machine-learning (ML) based classifier based on monitoring the current, voltage and state of charge and modifying one or more weight of the classifier as a part of validation. As a part of said machine-learning an inference-phase comprises re-capturing current, voltage and state of charge as input for the trained ML to diagnose at least one of a) presence or absence of fault in the battery; and b) a nature or type of the diagnosed fault.

Further, the method comprises diagnosing (step 106) at least one of: a current battery-state and a type of current battery state based on the one or more likelihood ratios as evaluated. The diagnosis comprises detecting presence or absence of a fault and thereby certifying the state of the battery as healthy or faulty. The detecting of the type of fault comprises classifying the fault as at least one of discharging fault, charging fault, and internal short circuit. The detecting the severity of the fault comprises grading the fault as low, medium or severe.

In an implementation, the diagnosis comprises calculating at least one health-probability threshold and one or more severity thresholds with respect to the battery during the training-phase. The presence or absence of fault during the inference-stage is identified based on the calculated health-probability thresholds. The detected fault is graded based on one or more severity thresholds.

Further, the method comprises suggesting, preventive measures for addressing the hazardous conditions due to the faults.

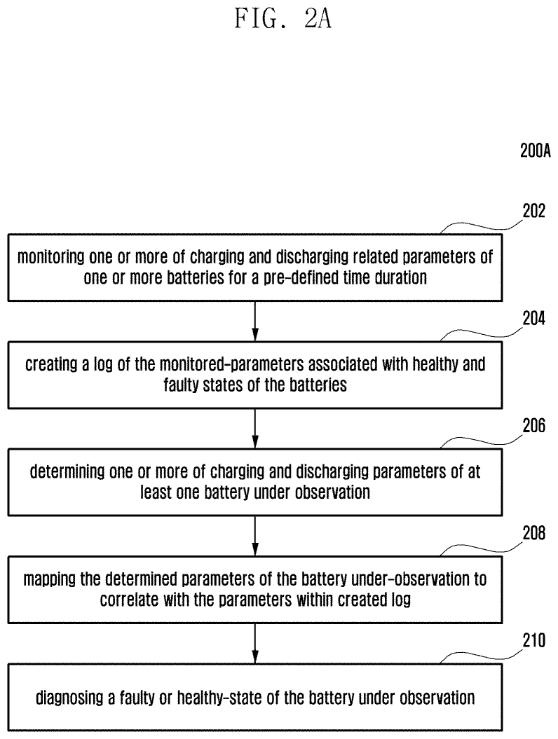

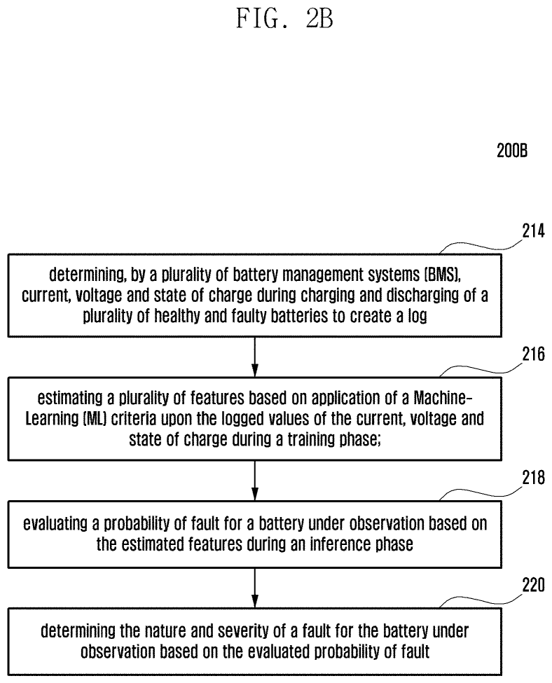

FIG. 2a illustrates a method 200A for fault diagnosis in a battery. The method comprises monitoring one or more of charging and discharging related parameters of one or more batteries for a pre-defined time duration (step 202). A log of the monitored-parameters associated with healthy and faulty states of the batteries is created (step 204). Further, determining one or more of charging and discharging parameters of at least one battery under observation (step 206). The determined parameters of the battery under-observation are mapped to correlate with the parameters within created log (step 208). Thereafter, a faulty or healthy-state of the battery under observation is diagnosed (step 210).

FIG. 2b illustrates a method 200B for battery fault diagnosis and prevention of hazardous conditions. The method comprises determining, by a plurality of battery management systems (BMS), current, voltage and state of charge during charging and discharging of a plurality of healthy and faulty batteries to create a log (step 214). A plurality of features are estimated based on application of a Machine-Learning (ML) criteria upon the logged values of the current, voltage and state of charge during a training phase (step 216). A probability of fault for a battery under observation is evaluated based on the estimated features during an inference phase (step 218). Based thereupon, the nature and severity of a fault for the battery under observation is determined based on the evaluated probability of the fault (step 220).

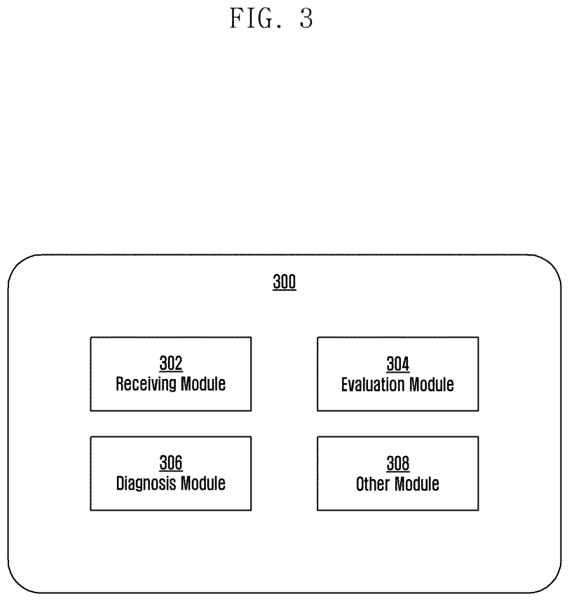

FIG. 3 illustrates a detailed internal-construction of a system 300 in accordance with an embodiment of the present disclosure. The system 300 includes a receiving module 302 that performs the step 102, an evaluation-module 304 that performs that step 104, and a diagnosis module 306 that performs the step 106. Likewise, there may be a miscellaneous module 308 within the system 300 that facilitate operational-interconnection among the modules 302 through 306 and perform other ancillary-functions.

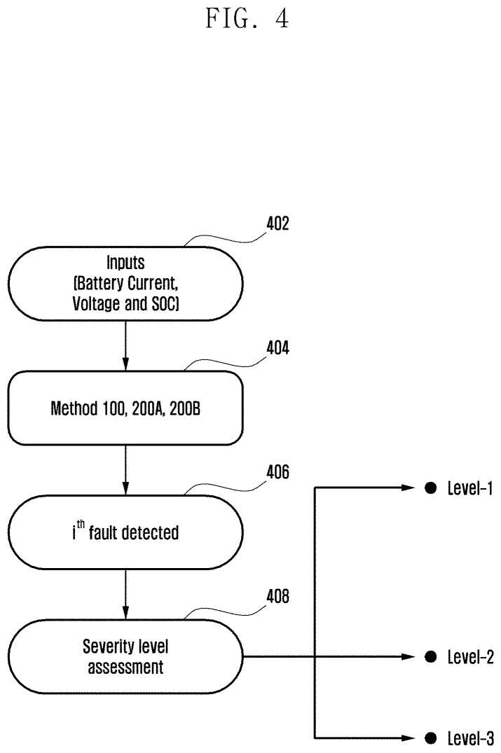

FIG. 4 illustrates an example implementation for diagnosing health of battery, over-discharging fault, over-charging fault, internal shot circuit (ISC) fault, and sounding an alert to a service center, etc.

Step 402 corresponds to determination of input parameters such as such Battery Current, voltage and state of charge (SOC).

Step 404 corresponds to application of method steps related to 100, 200A, and 200B, as illustrated in FIG. 1, FIG. 2a, and FIG. 2b.

Step 406 corresponds to detection of fault, for example as one or more of over-discharging fault, over-charging fault, or internal shot circuit (ISC) fault.

Step 408 corresponds to adopting various levels of corrective measures such as:

Example of Level 1 corrective measures are: switching off the device when the battery voltage falls below Vth and informing the users 30 min before shutdown, asking the users to use the standard charging adapter, and monitoring the device temperature. If the temperature is crossing the safe limit frequently, then adopting Level 2 measures.

Example of Level 2 corrective measures are switching off the device when the battery voltage falls below Vth and informing the users 30 min before shutdown, and monitoring the device temperatures. In this example, the user is asked to use the standard charging adapter and charging is stopped if the battery voltage is crossing Vth. In another example, the user is asked to connect to the charging adapter, switch off the device, and not to use the device any further. In yet another example, the SOC of the battery is maintained between 5% to 10% SOC by very slow charging, and if the temperature is frequently crossing a safe limit, then it may be suggested to the user to visit service centre.

Example of Level 3 corrective measures may be switching off the device when the battery voltage falls below Vth2 and informing the user 30 min before shutdown, stopping the charging if the battery voltage is crossing Vth2, asking the user to immediately stop using the phone, and keeping the device remote and safe. The user may be requested to visit the service centre immediately.

In a supplementary example, the battery health information is stored along with timestamp for rendering available for service centre.

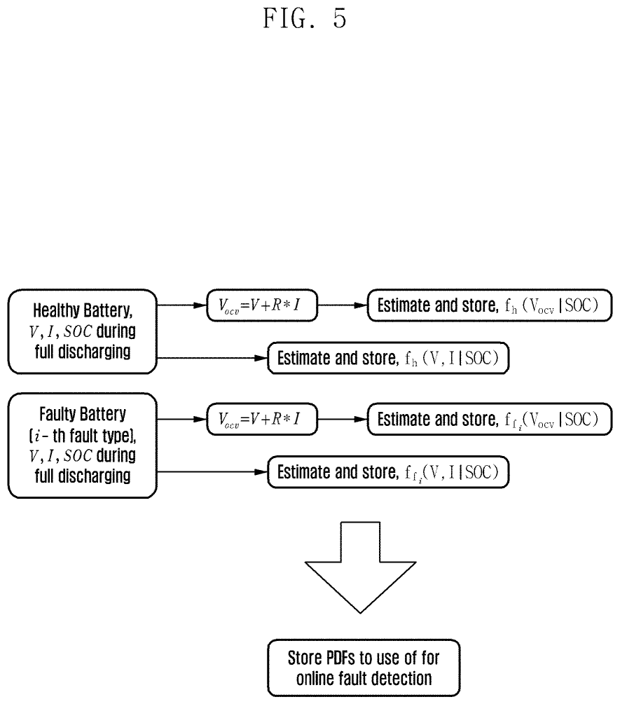

FIG. 5 illustrates an example implementation corresponding to FIG. 2a and renders an offline processing executed in that respect. More specifically, FIG. 5 illustrates creating and storing probability density functions (PDFs) to use for online fault detection. Following Table 1 illustrates the example-parameters for creating said PDFs.

TABLE 1

| | |
|---|---|
| V_{ocv} | Open circuit voltage (OCV) |
| R | Internal resistance of the battery |
| f(V_{ocv}\|SOC) | Probability density function (PDF) of OCV at |
| | different SOC levels. SOC changes in step of 1 and rounded |
| | of to integer. |
| f(V, I\|SOC) | Joint PDF of V&I at different SOC level |
| fₕ & f_{fi} | PDF under healthy case and PDF for faulty case of i-th fault |
| | type |

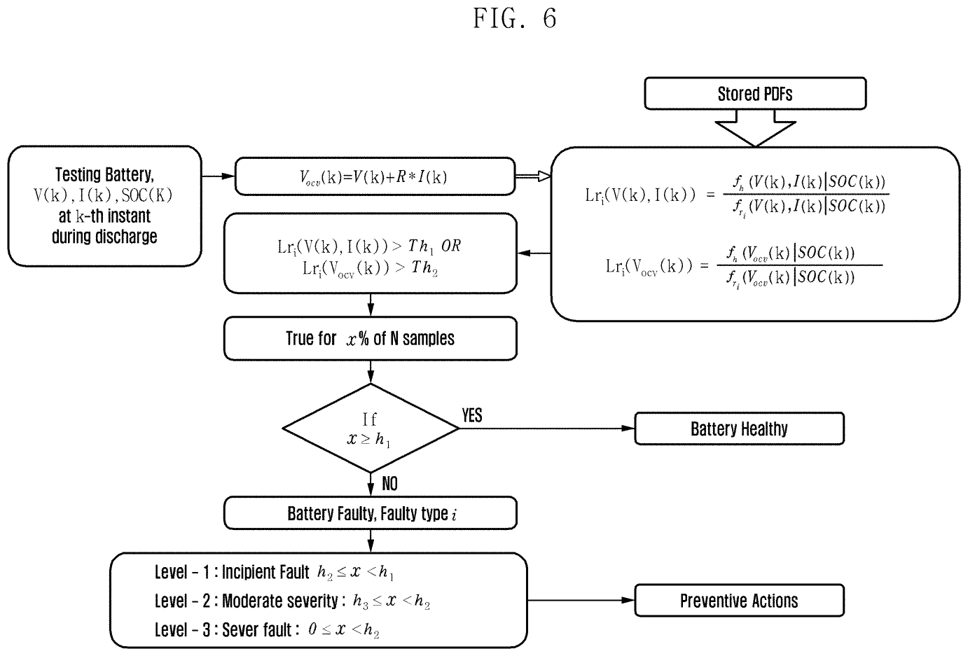

FIG. 6 illustrates an example implementation corresponding to FIG. 2a and renders an online monitoring executed in that respect. More specifically, FIG. 6 illustrates severity level assessment done through the steps 206, 208 and 210 corresponding to FIG. 2a. In an example, the severity levels may be assessed as
Level-1: Incipient Fault h_2≤x<h_1
Level-2: Moderate severity: h_3≤x<h_2
Level-3: Sever fault: 0≤x<h_2

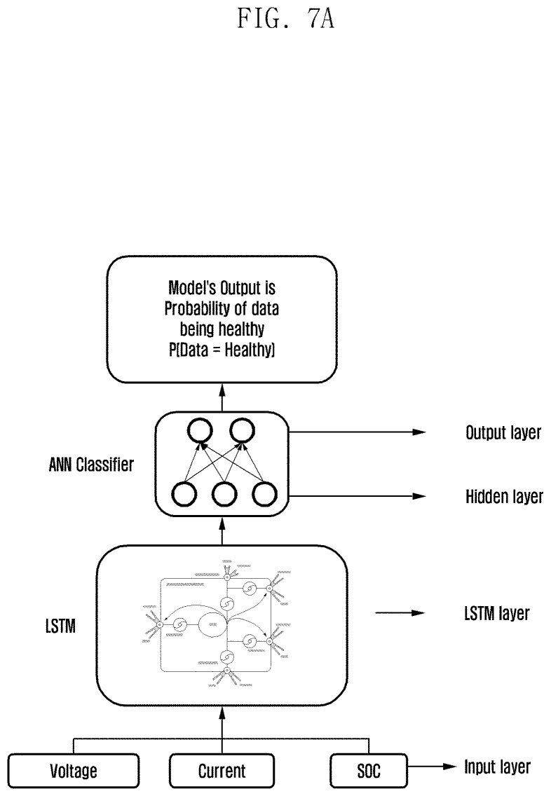

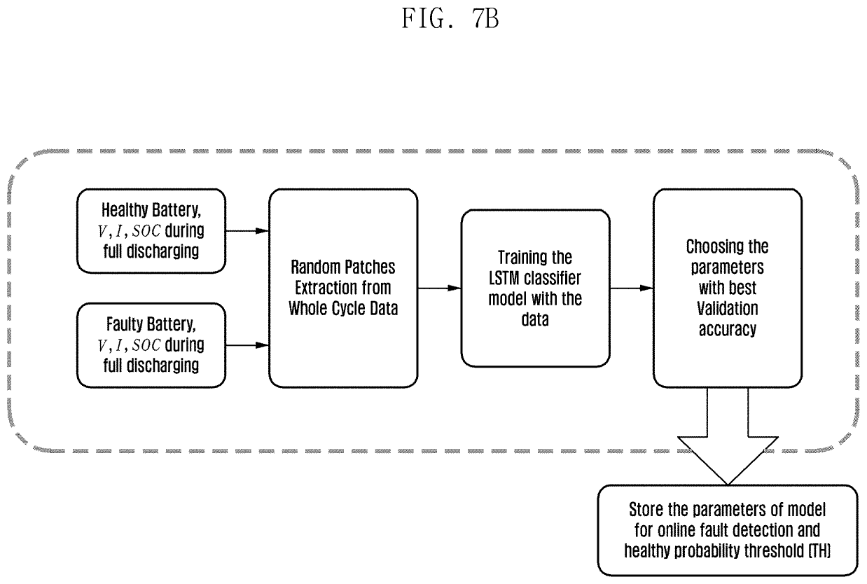

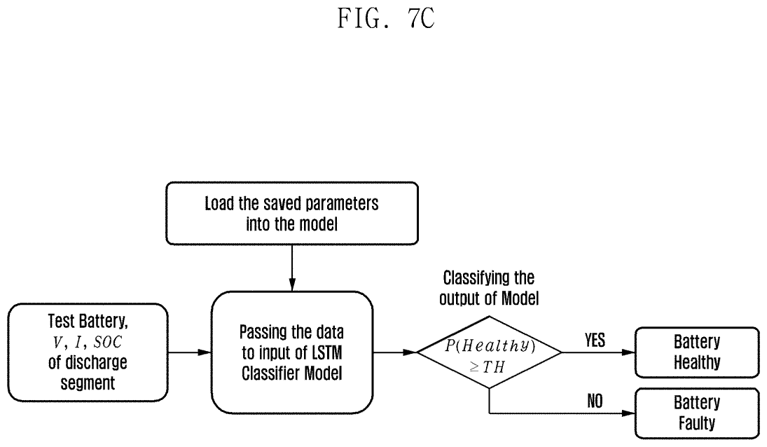

FIG. 7a illustrates an example LSTM Model based Architecture in respect of FIG. 2b, wherein LSTM refers a Long Short term memory network and TH refers a threshold obtained while training. The input layer corresponds to Voltage, current and SOC and output layer comprises an ANN classifier for rendering a Probability of data being healthy, i.e. P(Data=Healthy). P(Data=Healthy) is the output of LSTM Model which is “Probability of Data being healthy” and TH represents “Threshold obtained while training”.

FIG. 7b illustrates an example one time offline process (training) of LSTM with respect to FIG. 7a. The parameters for online fault detection and healthy probability threshold (TH) are outputted which are the stored.

FIG. 7c illustrates an example real time monitoring process with respect to FIG. 7a and illustrates the steps 214 to 220 of FIG. 2b. FIG. 7c corresponds to the execution of the steps 214 till 220 for estimating P(Data=Healthy). If P(Healthy)≥TH, then the Battery is declared Healthy otherwise unfit.

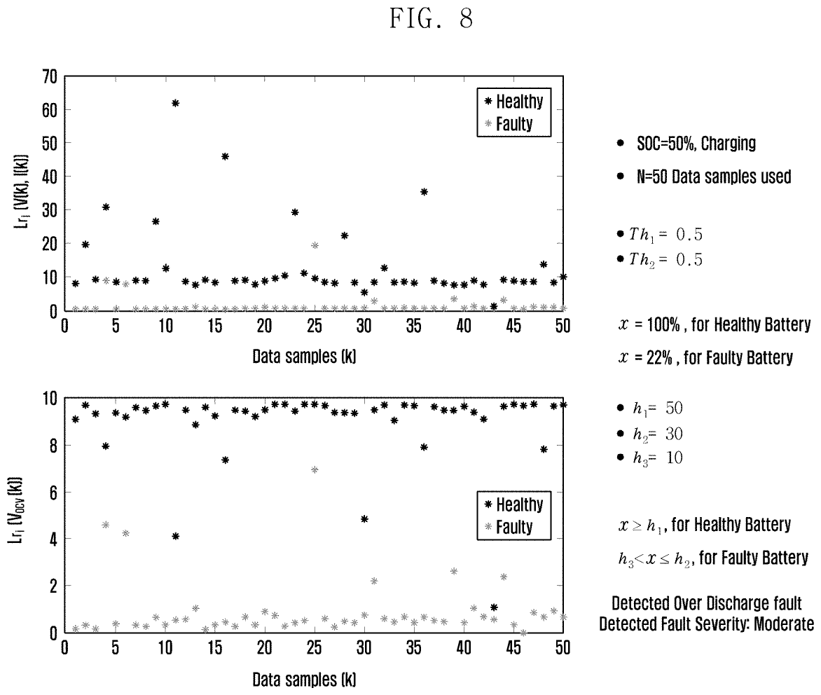

FIG. 8 illustrates an experiment test case illustrating an over discharge fault detection based on the FIG. 1 and FIG. 2a. As may be understood, “Over-Discharge” fault is detected with moderate severity.

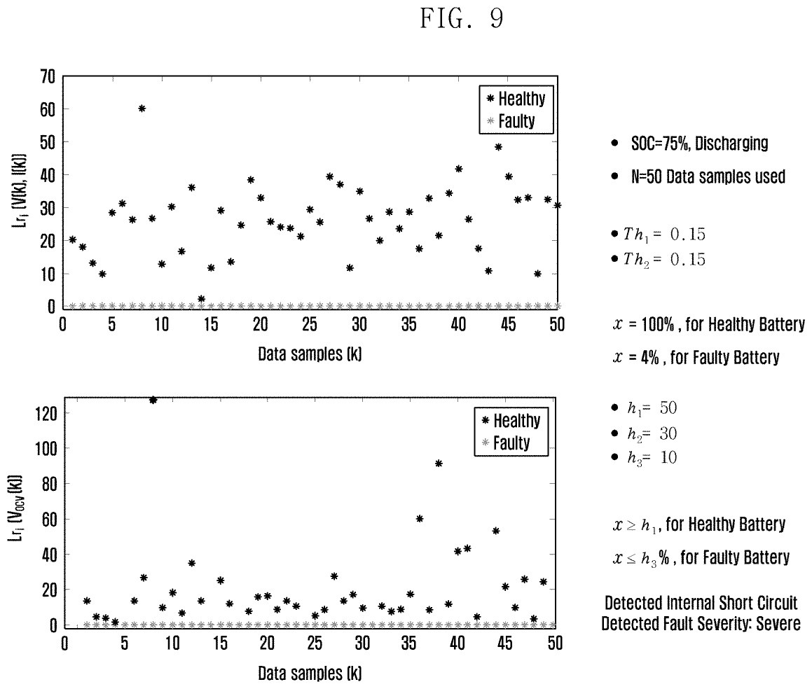

FIG. 9 illustrates an experiment test case Test Case illustrating “Internal Short Circuit fault detection” based on the FIG. 1 and FIG. 2a. As may be understood, “Internal Short Circuit fault” fault is detected with severe severity.

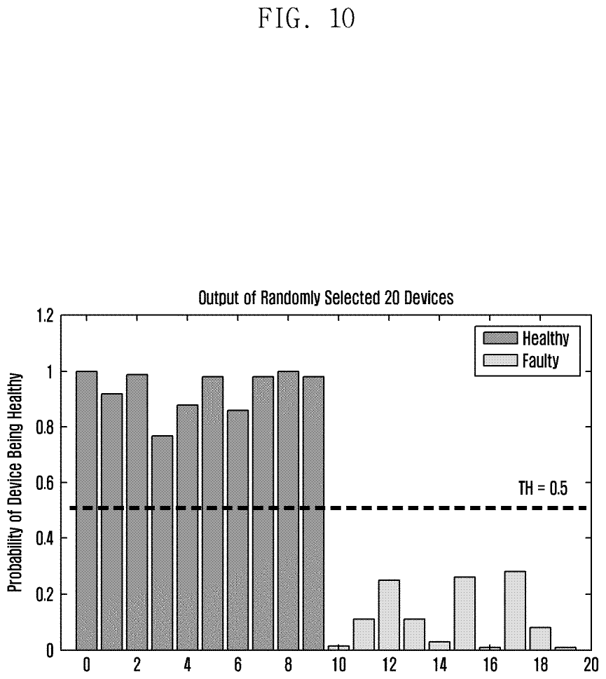

FIG. 10 illustrates an experiment test case Test Case illustrating “Internal Short Circuit fault detection” based on the FIG. 1 and FIG. 2b. As may be understood, out of 20 devices, 10 are observed as Healthy and 10 faulty.

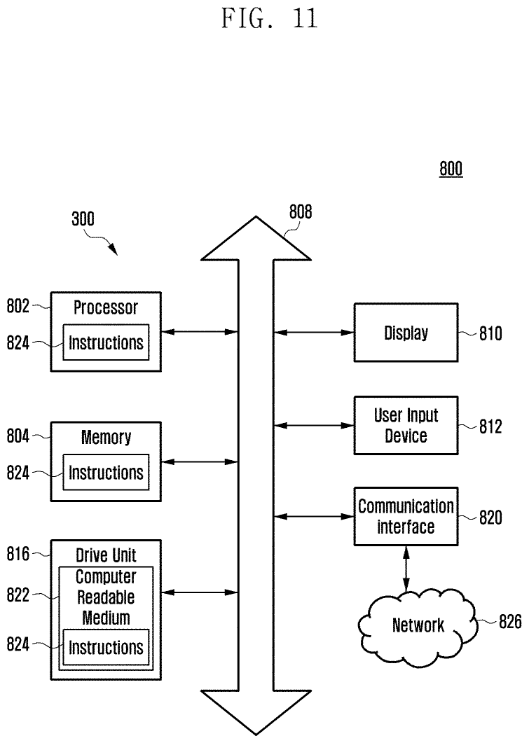

FIG. 11 shows yet another exemplary implementation in accordance with an embodiment of this disclosure, and further, another typical hardware configuration of the system 300 in the form of a computer system 800. The computer system 800 can include a set of instructions that can be executed to cause the computer system 800 to perform any one or more of the methods disclosed. The computer system 800 may operate as a standalone-device or may be connected, e.g., using a network, to other computer systems or peripheral devices.

In a networked deployment, the computer system 800 may operate in the capacity of a server or as a client user computer in a server-client user network environment, or as a peer computer system in a peer-to-peer (or distributed) network environment. The computer system 800 can also be implemented as or incorporated across various devices, such as a personal computer (PC), a tablet PC, a personal digital assistant (PDA), a mobile device, a palmtop computer, a laptop computer, a desktop computer, a communications device, a wireless telephone, a land-line telephone, a web appliance, a network router, switch or bridge, or any other machine capable of executing a set of instructions (sequential or otherwise) that specify actions to be taken by that machine. Further, while a single computer system 800 is illustrated, the term “system” shall also be taken to include any collection of systems or sub-systems that individually or jointly execute a set, or multiple sets, of instructions to perform one or more computer functions.

The computer system 800 may include a processor 802 e.g., a central processing unit (CPU), a graphics processing unit (GPU), or both. The processor 802 may be a component in a variety of systems. For example, the processor 802 may be part of a standard personal computer or a workstation. The processor 802 may be one or more general processors, digital signal processors, application specific integrated circuits, field programmable gate arrays, servers, networks, digital circuits, analog circuits, combinations thereof, or other now known or later developed devices for analysing and processing data. The processor 802 may implement a software program, such as code generated manually (i.e., programmed).

The computer system 800 may include a memory 804, such as a memory 804 that can communicate via a bus 808. The memory 804 may include, but is not limited to computer readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like. In one example, the memory 804 includes a cache or random access memory for the processor 802. In alternative examples, the memory 804 is separate from the processor 802, such as a cache memory of a processor, the system memory, or other memory. The memory 804 may be an external storage device or database for storing data. The memory 804 is operable to store instructions executable by the processor 802. The functions, acts or tasks illustrated in the figures or described may be performed by the programmed processor 802 for executing the instructions stored in the memory 804. The functions, acts or tasks are independent of the particular type of instructions set, storage media, processor or processing strategy and may be performed by software, hardware, integrated circuits, firm-ware, micro-code and the like, operating alone or in combination. Likewise, processing strategies may include multiprocessing, multitasking, parallel processing and the like.

As shown, the computer system 800 may or may not further include a display 810, such as a liquid crystal display (LCD), an organic light emitting diode (OLED), a flat panel display, a solid state display, a cathode ray tube (CRT), a projector, a printer or other now known or later developed display device for outputting determined information. The display 810 may act as an interface for the user to see the functioning of the processor 802, or specifically as an interface with the software stored in the memory 804 or in the drive unit 1016.

Additionally, the computer system 800 may include an input device 812 configured to allow a user to interact with any of the components of computer system 800. The computer system 800 may also include a disk or optical drive unit 816. The disk or optical drive unit 816 may include a computer-readable medium 822 in which one or more sets of instructions 824, e.g. software, can be embedded. Further, the instructions 824 may embody one or more of the methods or logic as described. In a particular example, the instructions 824 may reside completely, or at least partially, within the memory 804 or within the processor 802 during execution by the computer system 800.

The present disclosure contemplates a computer-readable medium that includes instructions 824 or receives and executes instructions 824 responsive to a propagated signal so that a device connected to a network 826 can communicate voice, video, audio, images or any other data over the network 826. Further, the instructions 824 may be transmitted or received over the network 826 via a communication port or interface 820 or using a bus 808. The communication port or interface 820 may be a part of the processor 802 or may be a separate component. The communication port or interface 820 may be created in software or may be a physical connection in hardware. The communication port or interface 820 may be configured to connect with a network 826, external media, the display 810, or any other components in computer system 800, or combinations thereof. The connection with the network 826 may be a physical connection, such as a wired Ethernet connection or may be established wirelessly as discussed later. Likewise, the additional connections with other components of the computer system 800 may be physical connections or may be established wirelessly. The network 826 may alternatively be directly connected to the bus 808.

The network 826 may include wired networks, wireless networks, Ethernet AVB networks, or combinations thereof. The wireless network may be a cellular telephone network, an 802.11, 802.16, 802.20, 802.1Q or WiMax network. Further, the network 826 may be a public network, such as the Internet, a private network, such as an intranet, or combinations thereof, and may utilize a variety of networking protocols now available or later developed including, but not limited to TCP/IP based networking protocols. The system is not limited to operation with any particular standards and protocols. For example, standards for Internet and other packet switched network transmission (e.g., TCP/IP, UDP/IP, HTML, HTTP) may be used

At least based on the aforesaid features, the present subject matter applies data driven techniques to the recorded battery current, voltage and SOC data from the BMS to detect different types of battery faults. The proposed solution also determines the severity of the problem and takes preventive actions depending on the type of the fault and its severity to prevent any hazardous incident and helps ensure user safety. Two different data driven techniques can be applied to solve the fault diagnosis problem. One of them is ML based method and another one is pure statistical likelihood ratio based method. Both the techniques can also be applied together to get more robust fault estimation. The proposed method can detect faults in almost real-time fashion (<1 min) which gives enough lead-time to prevent any subsequent hazardous incidents. The present subject matter is at least capable of:
Near real time battery fault detection and identification of fault type.
Takes actions to prevent any hazardous incident that may be caused by the faulty battery.
Data driven techniques are used for fault detection and isolation purposes.
Learning is offline and may need to be performed once for a single fault type and once for a healthy case.
Quick implementation as no training is required if the battery has similar electrochemistry.
Can be implemented in the existing BMS with no additional hardware required.
Low complexity and Low memory requirements.
Works in the background. No special charging pattern or resting of the battery is required.

The present subject matter may detect and isolate various battery faults. It can estimate the severity of the fault and takes preventive measures to help ensure user safety. It can work with partial and random charge-discharge pattern with nor-uniform or random sampled data. The present subject matter at least detects other battery faults along with ISC. It is online method and can detect faults when the battery is in use.

While specific language has been used to describe the disclosure, any limitations arising on account of the same are not intended. As would be apparent to a person in the art, various working modifications may be made to the method in order to implement the inventive concepts as taught herein.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein.

Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

Although the present disclosure has been described with various embodiments, various changes and modifications may be suggested to one skilled in the art. It is intended that the present disclosure encompass such changes and modifications as fall within the scope of the appended claims.

What is claimed is:

1. A method for battery fault diagnosis and prevention of hazardous conditions, the method comprising:
determining a plurality of parameters defined as one or more of current, voltage, or state of charge during operation of a battery-powered device;
evaluating one or more likelihood ratios related to malfunctioning of a battery based on at least one of:
estimation of probability density functions (PDFs) based on a historical monitoring of the current, voltage or state of charge; and
a real time monitoring of current, voltage, or state of charge of the battery based on a database of stored PDFs;
diagnosing at least one of: a current battery-state or a type of current battery state based on the one or more likelihood ratios evaluated.

2. The method of claim 1, wherein said determining of the plurality of parameters during the operation of the battery-powered device corresponds to a determination performed during charging and discharging of the battery associated with the battery-powered device.

3. The method of claim 1, wherein said plurality of parameters are determined based on a plurality of battery management systems (BMS) configured to track the operation of the battery with the battery-powered device.

4. The method of claim 1, wherein the likelihood ratios are evaluated based on at least one of:
collecting a first factor associated with a historical monitoring of the current, voltage, and state of charge of a healthy battery and a second factor associated with a historical monitoring of the current, voltage, and state of charge of a faulty battery; and
estimation of probability destiny functions (PDFs) using the first factor and the second factor.

5. The method of claim 1, wherein diagnosing at least one of: the current battery-state or the type of current battery state based on the one or more likelihood ratios evaluated further comprises:
detecting presence or absence of a fault; and
certifying the current battery-state as healthy or faulty.

6. The method of claim 5, wherein the detecting the presence or absence of the fault further comprises:
classifying the presence of the fault as at least one of discharging fault, charging fault, or internal short circuit.

7. The method of claim 5, wherein the detecting the presence or absence of the fault further comprises:
grading the fault as low, medium or severe.

8. The method of claim 1, further comprising: suggesting preventive measures for addressing hazardous conditions due to faults.

9. The method of claim 5, wherein a likelihood of battery-failure is computed at least based on:
a training-phase comprising training a machine-learning (ML) based classifier based on monitoring the current, voltage, and state of charge, and modifying one or more weight of a classifier as a part of validation; and
an inference-phase comprising re-capturing current, voltage, and state of charge as input for the trained ML to diagnose at least one of:
a) presence or absence of fault in the battery; and
b) a type of diagnosed fault.

10. The method of claim 9, wherein the diagnosing comprises:
calculating at least one health-probability threshold and one or more severity thresholds of the battery during the training-phase;
identifying presence or absence of fault during the inference-phase based on the calculated at least one health-probability threshold; and
grading the type of diagnosed fault based on one or more severity thresholds.

11. A method for fault diagnosis in a battery, the method comprising:
monitoring one or more of charging and discharging related parameters of one or more batteries for a pre-defined time duration;
creating a log of the monitored one or more charging and discharging related parameters associated with healthy and faulty states of the one or more batteries;
determining one or more of charging and discharging parameters of at least one battery under observation;
mapping the determined charging and discharging parameters of the battery under observation to correlate with the parameters within created log; and
diagnosing a faulty or healthy-state of the battery under observation.

12. A method for battery fault diagnosis and prevention of hazardous conditions, the method comprising:
determining, by a plurality of battery management systems (BMS), current, voltage, and state of charge during charging and discharging of a plurality of healthy and faulty batteries to create a log of values;
estimating a plurality of features based on application of a Machine-Learning (ML) criteria upon the logged values of the current, voltage, and state of charge during a training phase;
evaluating a probability of fault for a battery under observation based on the estimated plurality of features during an inference phase; and
determining a type of a fault and a severity of the fault for the battery under observation based on the evaluated probability of fault.

13. A computer system for battery fault diagnosis and prevention of hazardous conditions, the computer system comprising:
a memory;
a processor coupled to the memory and configured to:
determine a plurality of parameters defined as one or more of current, voltage, or state of charge during operation of a battery-powered device;
evaluate one or more likelihood ratios related to malfunctioning of a battery based on at least one of:
estimation of probability density functions (PDFs) based on a historical monitoring of the current, voltage, and state of charge;
real time monitoring of current, voltage, or state of charge of the battery based on a database of stored PDFs; and
diagnose at least one of: a current battery state or a type of current battery state based on the one or more likelihood ratios as evaluated.

14. The computer system of claim 13, wherein determine the plurality of parameters during the operation of the battery-powered device corresponds to a determination performed during charging and discharging of the battery associated with the battery-powered device.

15. The computer system of claim 13, wherein the plurality of parameters are determined based on a plurality of battery management systems (BMS) configured to track the operation of the battery with the battery-powered device.

16. The computer system of claim 13, wherein the processor is further configured to:
evaluate the likelihood ratios based on at least one of:
collect a first factor associated with a historical monitoring of the current, voltage, and state of charge of a healthy battery and a second factor associated with a historical monitoring of the current, voltage, and state of charge of a faulty battery; and
estimation of probability destiny functions (PDFs) using the first factor and the second factor.

17. The computer system of claim 13, wherein to diagnose at least one of: a current battery-state or a type of current battery state based on the one or more likelihood ratios as evaluated, the processor is further configured to:
detect a presence or an absence of a fault; and
certify the current battery state as healthy or faulty.

18. The computer system of claim 17, wherein to detect the presence or absence of the fault, the processor is further configured to:
classify the presence of the fault as at least one of discharging fault, charging fault, or internal short circuit.

19. A system for fault diagnosis in a battery, the system comprising:
a receiving module for:
monitoring one or more of charging and discharging related parameters of one or more batteries for a pre-defined time duration;
creating a log of the monitored charging and discharging related parameters associated with healthy and faulty states of the batteries;
determining one or more of charging or discharging parameters of at least one battery under observation;
an evaluation module for mapping the determined charging and discharging parameters of the at least one battery under observation to correlate with the parameters within created log; and
a diagnosis module for diagnosing a faulty or healthy-state of the at least one battery under observation.

20. A system for battery fault diagnosis and prevention of hazardous conditions, the system comprising:
a receiving module for:
determining, by a plurality of battery management systems (BMS), current, voltage, and state of charge during charging and discharging of a plurality of healthy and faulty batteries to create a log of values;
estimating a plurality of features based on application of a Machine-Learning (ML) criteria upon the logged values of the current, voltage, and state of charge during a training phase;
an evaluation module for evaluating a probability of fault for a battery under observation based on the estimated plurality of features during an inference phase; and
a diagnosis module for determining the type of a fault and a severity of the fault for the battery under observation based on the evaluated probability of fault.
